(19) United States
(12) Patent Application Publication
(10) Pub. No.: US 2009/0245536 A1
(43) Pub. Date: Oct. 1, 2009

(54) SYSTEM AND METHOD FOR SETTING VOLUME SETTINGS IN AN AUDIO SYSTEM

(76) Inventor: Freimann Felix, Sunnyvale, CA (US)

Correspondence Address: NORTH AMERICA INTELLECTUAL PROPERTY CORPORATION, P.O. BOX 506, MERRIFIELD, VA, 22116, US

(21) Appl. No.: 12/055,296

(22) Filed: Mar. 25, 2008

(51) Int. Cl. H03G 3/00

(52) U.S. Cl. 381/104; 381/107

(57) ABSTRACT

A system and method for switching between a plurality of audio settings is disclosed. The system includes: an audio processing system for receiving audio data from an audio data source, including: a central processing unit (CPU) for storing a plurality of volume settings; and a toggle switch for toggling between the plurality of volume settings to select a volume setting. The audio system also includes a displaying device for displaying audio data received from the audio processing system according to the selected volume setting. The method includes: assigning a first volume setting for an audio data and saving the first volume setting; assigning a second volume setting for the audio data and saving the second volume setting; and toggling between the first volume setting and the second volume setting so the audio data is played at either the first volume setting or the second volume setting.

### BACKGROUND

Modern life is increasingly characterized by convenience and efficiency. Greater affluence has led to many hi-tech products being available to a large majority of the population, and users have a wide variety of products from which to choose. In such a market, convenience of use is a factor in most consumers' product buying decisions.

Various kinds of audio media have varying ranges of volume; for example, advertisements are at a considerably louder volume than scheduled programming, movies can vary between periods of quiet and loud periods etc. This sudden change in volume can be annoying to a user, or inconvenient to other people in the vicinity. At present, a user only has the option of utilizing the ‘mute’ button, or adjusting the volume up or down in the conventional manner. If the volume is muted completely, the user will miss some of the programming. Adjusting the volume manually may not be fast enough to prevent the annoyance to other people. Therefore, a new system for controlling volume is needed.

### SUMMARY

With this in mind, the present invention provides a system and method for setting a plurality of volume settings for audio data, and means for directly switching between the audio settings without needing to continually adjust the volume by the conventional method.

A method according to an exemplary embodiment of the present invention is disclosed. The method comprises: assigning a first volume setting for an audio data and saving the first volume setting; assigning a second volume setting for the audio data and saving the second volume setting; and toggling between the first volume setting and the second volume setting so the audio data is played at either the first volume setting or the second volume setting.

Additionally, a system according to an exemplary embodiment of the present invention is disclosed. The system comprises: a displaying device, for displaying received audio data; a central processing unit (CPU), for storing a plurality of audio settings; and a toggle switch, for toggling between the plurality of audio settings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a system according to the exemplary embodiment of the present invention.

FIG. 2 is a flowchart detailing the steps of a method according to an exemplary embodiment of the present invention.

### DETAILED DESCRIPTION

The aim of the present invention is to provide a system and method that enable a user to set a plurality of volume settings to audio media, and means for quickly switching between these settings. The present invention primarily achieves this by use of a toggle switch to toggle between the settings.

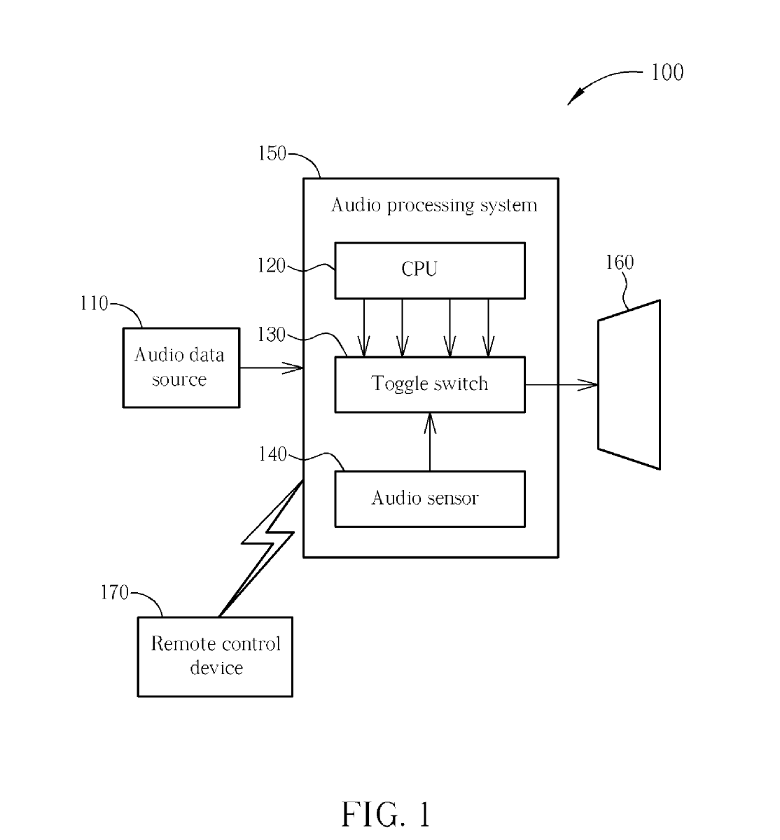

Please refer to FIG. 1. FIG. 1 is a diagram of an audio system 100 for receiving and displaying audio data. The audio system 100 comprises an audio data source 110, which could be an Internet source, optical media such as a CD or DVD, or protected media etc. The audio system 100 also comprises an audio displaying device 160, which is represented as, but not limited to, a speaker, and an audio processing system 150, which includes a Central Processing Unit (CPU) 120, a toggle switch 130, and an audio sensor 140. Please note that not all these components are required for each embodiment of the present invention. Initially, audio data is received from the audio data source 110. The audio system 100 could be a purely audio system such as a radio, or could be an audio-visual system such as a television. A user utilizes a conventional remote control device 170 to input at least two volume settings to the audio system 100, which saves the volume settings to the CPU 120. The user then utilizes a toggle switch (not shown) on the remote control device 170 to control the toggle switch 130, which selects one of the saved volume settings in the CPU. When an event occurs that requires a different volume setting, for example being interrupted by a phone call, or a loud section of the audio media, the user merely needs to toggle the toggle switch 130 once to switch to a second saved volume setting.

While viewing audio data at one of the preset volume settings, the user still has the option of adjusting the volume by increments utilizing the conventional ‘volume up’ and ‘volume down’ buttons (not shown) on the remote control device 170. The user then has the option of saving the adjusted volume setting as one of the preset volume settings, or keeping the original setting.

It should be obvious to those skilled in this art that the present invention is not limited to two volume settings. A plurality of volume settings can be input to the audio system 100, and the toggle switch 130 similarly used for toggling between all volume settings.

In a situation where the audio data source is an external media such as an optical disc, many systems save a last time played position of the optical media, so a next time the optical media is accessed the user has the option of viewing the data from the last place viewed or from the beginning of the disc. When the user sets the plurality of volume settings for the audio data, therefore, the audio system 100 can store these settings to the CPU 120 so each time the audio data source 110 is accessed the volume settings are already preset in the CPU 120.

In the above example, toggling between the volume settings is directly performed by a user. In some situations, however, the toggling can be performed automatically in response to external stimuli. For example, when driving a car, background noise requires the volume of a radio (for example) to be at a high setting when driving at high speeds, but when entering a residential area the volume should be reduced. For safety reasons, distractions to the driver should be minimized. The audio system 100 therefore comprises an audio sensor 140 for detecting background noise, where the audio sensor 140 is coupled to the toggle switch 130. The volume settings are set by the user, but the toggle switch 130 is toggled automatically between the volume settings in direct response to the background noise detected by the audio sensor 140.

A variation of this method comprises the user setting volume settings according to the type of media. For example, it may be desirable to have sports and music programs at a higher volume setting than news and current affairs. In cable television systems the channels are often organized according to content, therefore the toggle switch 130 toggles between the volume settings according to which channel is selected. Please note that this is just one example, and many other modifications fall within the scope of the present invention.

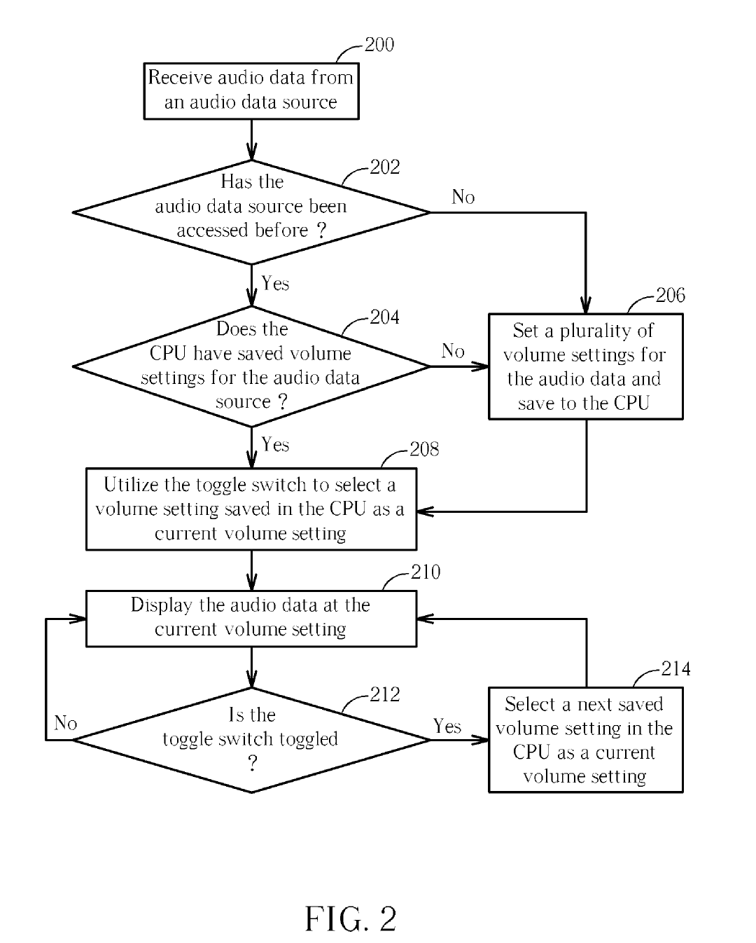

For a clear description of the method of the present invention, please refer to FIG. 2. FIG. 2 is a flowchart detailing the steps of the method. The steps are as follows:
Step 200: Receive audio data from an audio data source;
Step 202: Has the audio data source been accessed before? If yes go to Step 204, if no go to Step 206;
Step 204: Does the CPU have saved volume settings for the audio data source? If yes go to Step 208, if no go to Step 206;
Step 206: Set a plurality of volume settings for the audio data and save to the CPU;
Step 208: Utilize the toggle switch to select a volume setting saved in the CPU as a current volume setting;
Step 210: Display the audio data at the current volume setting;
Step 212: Is the toggle switch toggled? If yes go to Step 214, if no go back to Step 210;
Step 214: Select a next saved volume setting in the CPU as a current volume setting. Go back to Step 210.

The utilization of the toggle switch 130 for switching between saved volume settings allows a displaying volume of audio data to be quickly and directly adjusted to a desired volume. The toggling of the toggle switch 130 can be directly performed by a user, or performed automatically in response to certain stimuli such as content of the audio data, or background noise etc. Furthermore, the saved volume settings can be adjusted at any time by a user.

Those skilled in the art will readily observe that numerous modifications and alterations of the device and method may be made while retaining the teachings of the invention.

What is claimed is:

1. A method for setting volume settings in an audio system, the method comprising:
assigning a first volume setting for an audio data and saving the first volume setting;
assigning a second volume setting for the audio data and saving the second volume setting; and
toggling between the first volume setting and the second volume setting so the audio data is played at either the first volume setting or the second volume setting.

2. The method of claim 1, wherein during playing of the audio data, the first volume setting or the second volume setting can be adjusted by a user control.

3. The method of claim 1, wherein the steps of assigning the first volume setting and assigning the second volume setting are performed by a user control.

4. The method of claim 1, wherein the steps of assigning the first volume setting and assigning the second volume setting are performed by the audio system according to content of the audio data.

5. The method of claim 1, further comprising:
receiving the audio data from an external medium source;
wherein the audio system saves the first volume setting and the second volume setting of the external medium source for a next time of accessing the external medium source.

6. The method of claim 1, wherein the step of toggling between the first volume setting and the second volume setting comprises:
detecting a background noise level to generate a detection result; and
toggling between the first volume setting and the second volume setting according to the detection result.

7. An audio system for setting volume settings, the audio system comprising:
an audio processing system for receiving audio data from an audio data source, the audio processing system comprising:
a central processing unit (CPU) for storing a plurality of volume settings; and
a toggle switch, coupled to the CPU, for toggling between the plurality of volume settings to select a volume setting; and
a displaying device, coupled to the audio processing system, for displaying audio data received from the audio processing system according to the selected volume setting.

8. The audio system of claim 7, further comprising a remote control device, wherein the toggle switch is controlled by the remote control device.

9. The audio system of claim 7, wherein during displaying of the audio data, the selected volume setting can be adjusted by a user control.

10. The audio system of claim 7, wherein the plurality of volume settings are assigned by a user control.

11. The audio system of claim 7, wherein the plurality of volume settings are assigned by the CPU according to content of the audio data.

12. The audio system of claim 7, wherein the audio data source is an external medium source, and the audio system saves the volume settings of the external medium source for a next time of accessing the external medium source.

13. The audio system of claim 7, further comprising:
an audio sensor, coupled to the toggle switch, for detecting a background noise level;
wherein the toggle switch is toggled in response to the background noise level.
